(19) United States
(12) Patent Application Publication
(10) Pub. No.: US 2005/0116924 A1
(43) Pub. Date: Jun. 2, 2005

(54) Micro-electromechanical switching backplane

(75) Inventors: Michael D. Sauvante, Santa Barbara, CA (US); Nicholas F. Pasch, Pacifica, CA (US); Glenn C. Sanders, Mountain View, CA (US)

Correspondence Address: CARPENTER & KULAS, LLP, 1900 EMBARCADERO ROAD, SUITE 109, PALO ALTO, CA, 94303, US

(73) Assignee: Rolltronics Corporation, Menlo Park, CA (US)

(21) Appl. No.: 10/959,604

(22) Filed: Oct. 5, 2004

Related U.S. Application Data
(60) Provisional application No. 60/509,753, filed on Oct. 7, 2003.

(51) Int. Cl. G09G 3/36; G09G 3/34

(52) U.S. Cl. 345/108

(57) ABSTRACT

A low cost, scalable backplane for black and white or color optical displays comprises a multi-membrane plastic structure on which is printed or deposited row and column drivers to form a matrix of micro electromechanical (MEM) switches. Each switch controls the state of a pixel in the optical display device. Critical to successful long-term operation, the backplane includes the controlled application of voltages to each switch so that the display functions correctly and display life is maximized. The MEM switches include a substantially non-pliable membrane and a substantially flexible membrane both of which include electrodes that when energized will create electrostatic forces that attracts the flexible membrane to the non-pliable membrane. The MEM switches are manufactured in an array with a pitch that provides a sufficient number of switches to drive an optical display device and each switch may be latched to eliminate the need to constantly refresh the device.

### CROSS-REFERENCES TO RELATED APPLICATIONS

This application is related to commonly assigned provisional patent application entitled “ELECTROMECHANICAL ACTIVE DISPLAY BACKPLANE AND IMPROVEMENTS THEREOF” by Michael Sauvante et al, application No. 60/509,753, filed on Oct. 7, 2003, the entire disclosure of which is herein incorporated by reference.

### BACKGROUND OF THE INVENTION

1. Field of the Invention

Embodiments of the present invention relate to optical display devices. More particularly, embodiments of the present invention relate to a low cost flat panel or electrophoretic display having a micro-electromechanical backplane.

2. Description of the Background Art

Optical displays such as liquid crystal displays (“LCDs”), plasma displays and organic light emitting displays (OLEDs), electro-luminescent displays, electronic ink paper displays and other pixel-based displays are used in many products such as computer displays, cellular telephones, flat screen televisions, watches, entertainment devices, microwave ovens and many other electronic devices. Today's optical displays rely on a matrix of thin film transistors and (often) corresponding capacitors, deposited on a glass membrane, to control individual pixels. This transistor and capacitor matrix is often referred to as an “active matrix display backplane” or backplane for short. By applying a voltage to a row electrode and a column electrode, the transistor at the intersection of the row and column controls the pixel while the capacitor holds the charge until the next refresh cycle.

In the conventional active matrix backplane, row and column drivers (generated by electronic circuits that are well known in the art) generate linear voltages while the transistor generates a nonlinear response in the selected pixel or optical cell. A typical optical cell of the type called the liquid crystal cell or the electrophoretic cell is intrinsically slightly nonlinear in its optical response to linear voltages. Were this not the case, the so-called “Passive Matrix” display would not be possible. The transistor in the active matrix backplane exaggerates the nonlinearity of the voltage applied to the row and column crossbar to provide a significant amplification of the row-column select function to cause the optical cell to act more like an ON/OFF switch. By this mechanism of amplification of the select power, the display can create acceptable images without the problems of poor contrast and ghosting seen in passive matrix displays.

While optical display technology is constantly evolving, the size of the display has been limited by manufacturing problems associated with creating larger and denser backplanes. Specifically, as the number of thin film transistors on a backplane increase, the likelihood of defective transistors increases disproportionately so manufacturers are forced to invest heavily in developing and procuring semiconductor processing equipment. Indeed, manufacturing process for large format optical displays suffers a high percentage of rejects due to non-functional transistors. Because of the poor yield, the consumer is burdened with high pricing for flat screen optical displays. To improve yields, manufacturers must spend ever-increasing amounts of capital to purchase expensive precision equipment to manufacture the silicon thin film transistors to satisfy the need for large format displays but there is little profit margin so there is no incentive to reduce the pricing to the consumer.

In large-scale optical displays, the backplane accounts for a significant portion of the overall manufacturing cost of the display because of the costs associated with manufacturing the transistor and capacitor matrix. Additional cost is associated with the membrane, which for virtually all such display backplanes is glass. Glass, unfortunately, is heavy, non-pliable and prone to breakage. To reduce weight, the thickness of the glass has been reduced with each succeeding generation of products but as the thickness is reduced, there is a significant negative impact on manufacturing yield with breakage of the glass membrane approaching 50% during the manufacture process. While plastic membranes are known, it is not a simple task to manufacture silicon transistors on a plastic membrane, primarily because plastic is not well suited to the high process temperatures associated with manufacturing silicon thin film transistors. Thus, plastic backplanes have not proven to be economically successful, when the manufacturing process is based upon straightforward variations of silicon-on-glass manufacturing technology. Further, the reliability of prior art silicon-on-plastic backplanes has been poor.

While many consumers desire large format displays, the cost to manufacture large silicon-on-glass backplanes using new tools, such as the commonly referred to Generation 6 fab, is high. While these tools are able to manufacture backplanes on 35″ glass plates, economies of scale do not offset the reduction in manufacturing yields. The result is an industry with high capital expenditures, low profit margins and high consumer costs.

### SUMMARY OF EMBODIMENTS OF THE INVENTION

Embodiments of the present invention provide a matrix of micro electro-mechanical (MEM) switches that can be manufactured using low cost printing techniques on plastic or other membranes. The MEM switches include a substantially non-pliable membrane and a substantially flexible membrane both of which include electrodes that when energized create electrostatic forces that attracts the flexible membrane to the non-pliable membrane. The matrix of MEM switches can be incorporated into the backplane structure of an optical display. Advantageously, the MEM switches can create similar nonlinear switching output characteristics to the semiconductor-based “active matrix” backplane.

In one embodiment the MEM switches include a “latching” mechanism such that once closed, the switch will remain in a closed state until instructed to release the state, thereby allowing for displays that do not require continuous and power wasting refreshing. The mechanism of the switch activation involves the electrostatic deflection of one or more polymer flexible membranes, to which have been attached conductive traces. One of the membranes is in intimate contact with an electrophoretic material, and the electric field induced by the electrostatic deflection and an optional latching mechanism can cause a change of state of the electophoretic material from e.g., black to white or one color to another.

Embodiments of he MEM switches herein described can be simple to manufacture and of good quality in operation. To improve the operational lifetime of the switches; it is herein also disclosed that there are several mechanisms involving materials selection and electrical interface design that significantly increase the lifetime over what would be expected from common practice. It is by the combination of the switch design, and the associated reliability improvements that this electromechanical backplane design is reliable and inexpensive to manufacture.

One embodiment of the present invention provides a low cost, scalable backplane for optical displays. The backplane preferably comprises a multi-membrane plastic structure on which is patterned row and column drivers to form the matrix of electromechanical micro switches. Each switch controls the state of a pixel in the optical display device. Critical to successful long-term operation, the present invention includes the application of control voltages to each switch so that the display functions correctly and display life is maximized. With the present invention, it is possible to replace the silicon-on-glass thin film transistors based backplanes with a matrix of MEM switches that are readily manufactured at low process temperatures and with inexpensive equipment. Further, the present invention enables the manufacture of scalable large optical displays on plastic membranes at low cost. Further still, the present invention enables the manufacture of optical displays that may be flexed or twisted into novel shapes while still maintaining the display properties.

In another embodiment, each MEM switch may be operated in a latched mode, such that once a pixel state is defined, it will remain in that state until changed thereby creating a bi-stable display device. In yet another embodiment, the switch need not be operated in a latch mode but rather the switches are periodically refreshed by the control electronics.

The matrix of MEM switches comprise a plastic membrane on which is printed a plurality of column electrodes. A spacer layer is printed onto the membrane to form a cell or perimeter around each column electrode where each cell defines either a pixel or a portion of a pixel. The spacer layer couples a flexible membrane to the plastic membrane such that the flexible membrane is nominally maintained in a spaced-apart relationship relative to the plastic membrane. A plurality of row electrodes is printed on the flexible membrane. When appropriate voltages are applied to the row and column electrodes, the flexible membrane will deflect or bend and make mechanical contact with the plastic membrane.

When the mechanical connection is made, electrical components are provided on the membranes such that an electrical circuit is formed to energize a display medium disposed on the side of the plastic membrane that is facing away from the flexible membrane. When the display medium is energized, it defines an ON state for that pixel or portion of a pixel. The display medium may be an electrophoretic display medium or other display medium such as OLED or liquid crystal. In the case of OLED displays, voltage is applied to the display medium through a via connection formed in the plastic membrane. When the electrical circuit is broken the electrostatic force holding the two membranes in mechanical contact is lost and the two membranes will separate or return to the OFF state where the pixel is in the dark or non-emitting state.

These provisions together with other various provisions and features are attained by devices, assemblies, systems and methods of embodiments of the present invention, various embodiments thereof being shown with reference to the accompanying drawings, by way of example only and not by way of any limitation.

### BRIEF DESCRIPTION OF THE DRAWINGS

FIG. 1 is a sectional side view of an exemplary cell of an exemplary micro-electromechanical switch in an OFF state in accordance with an embodiment of the present invention.

FIG. 2 is a sectional side view of an exemplary cell of an exemplary micro-electromechanical switch in an ON state in accordance with an embodiment of the present invention.

FIG. 3 is a sectional side view of a portion of a row of cells in a matrix of micro-electromechanical switches in accordance with an embodiment of the present invention.

FIG. 4 is a plan view of the non-pliable membrane of the cell of the exemplary micro-electromechanical switch shown in FIG. 1 with a latching topology.

FIG. 5 is a plan view of the flexible membrane of the cell of the micro-electromechanical switches in accordance with an embodiment of the present invention with a latching topology.

FIG. 6 is another plan view of the non-pliable membrane of the cell of an exemplary micro-electromechanical switch in accordance with an embodiment of the present invention for a non-latching topology.

FIG. 7 is a plan view of a row portion of the cell of an exemplary micro-electromechanical switch in accordance with an embodiment of the present invention for a non-latching topology.

FIG. 8 is a plan view of an alternative row portion of the cell of the exemplary micro-electromechanical backplane shown in FIG. 7.

FIG. 9 is an illustration of a system block diagram in accordance with an embodiment of the present invention.

FIG. 10 is a sectional side view of a portion of a cell of an exemplary micro-electromechanical switch in accordance with an embodiment of the present invention.

FIG. 11 illustrates a voltage-timing diagram for operating a cell of an exemplary micro-electromechanical switch in accordance with an embodiment of the present invention.

FIG. 12 illustrates another voltage timing diagram for operating a cell of an exemplary micro-electromechanical switch in accordance with an embodiment of the present invention.

### DETAILED DESCRIPTION OF EMBODIMENTS OF THE INVENTION

In the description herein for embodiments of the present invention, numerous specific details are provided, such as examples of components and/or methods, to provide a thorough understanding of embodiments of the present invention. However, embodiments of the invention can be practiced without one or more of the specific details, or with other apparatus, systems, assemblies, methods, components, materials, parts, and/or the like. In other instances, well-known structures, materials, or operations are not specifically shown or described in detail to avoid obscuring aspects of embodiments of the present invention.

A preferred embodiment of uses an array of mechanical switches controlled by row/column electrodes that are accessible by drivers similar in operation to ones currently used in prior art optical displays. The array is used to create nonlinear voltage or current switching responses that are applied or impressed on the optical cells of the display to generate an image. Note that other types of display technologies or electrical design or fabrication techniques can be used in conjunction with those specific technologies, designs or techniques described herein. For example, features of the MEM switching approach can be used with any type of actuator, switch, chemical or physical device or property, etc., to cause an effect suitable for imaging in an optical display. In general, any type of suitable driver or drive signal can be used.

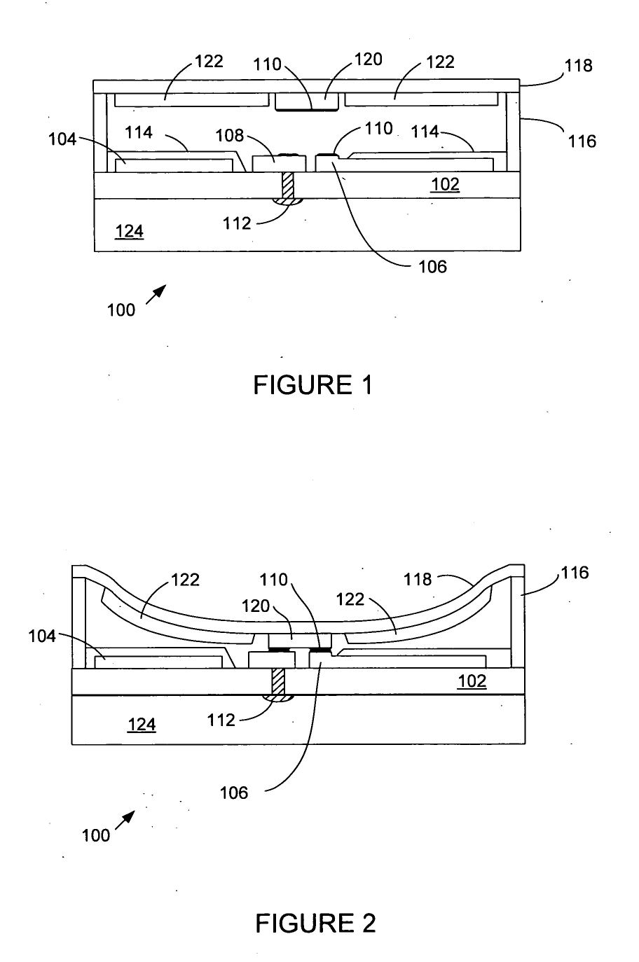

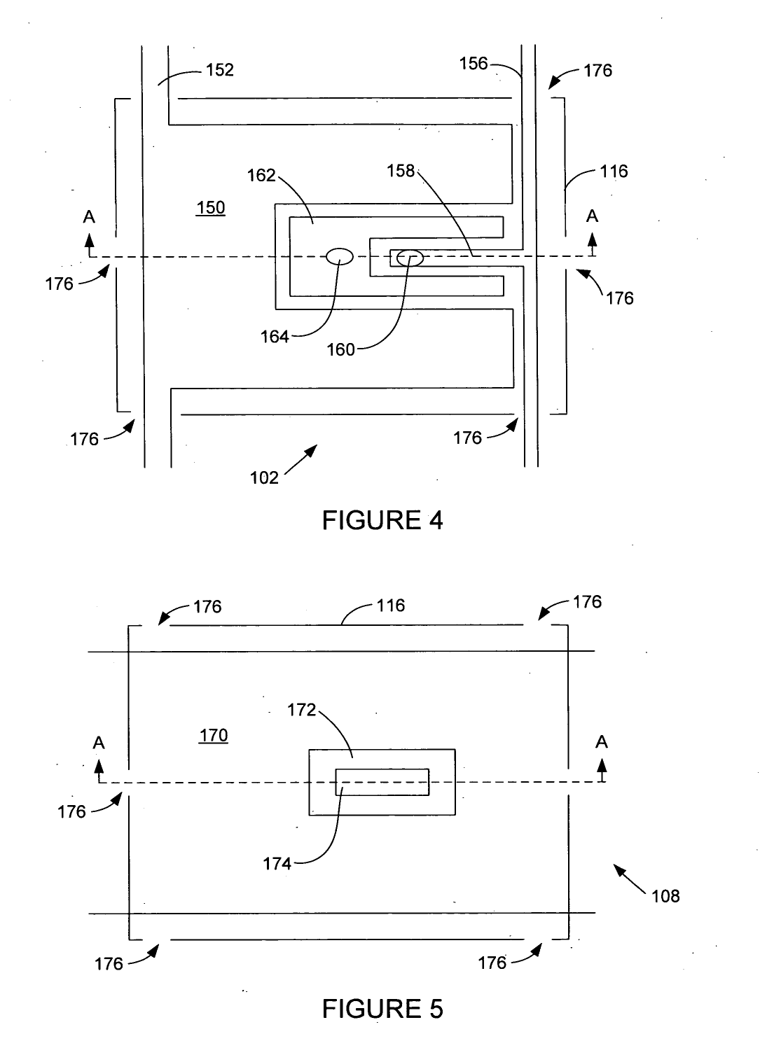

Referring now to the drawings more particularly by reference numbers, an exemplary cell 100 of a micro-electromechanical switch in accordance with an embodiment of the present invention is shown in FIGS. 1 and 2. Cell 100 is a sectional side view taken along section line A-A of FIGS. 4 and 5 and cell 100 is not drawn to scale. In a scalable optical display, millions of such cells will be arrayed in a matrix or other pattern to effectuate an intended display image. When used in a display embodiment, each cell 100 controls an individual pixel. By creating an electrostatic force, opposing foils in each cell are selectively controlled to form an electrical contact between two conductors. When the conductors come into contact, a circuit is completed that delivers the necessary power to the pixel. The matrix of cells is ideally suited to function as the backplane for a variety of display types such as liquid crystal displays (“LCD”), plasma displays, organic light emitting displays (OLED), electro-luminescent displays, electronic ink paper displays or other pixel-based displays. In other applications, such as by way of example, cell 100 securely stores digital information with minimal power requirements by performing the function of a silicon transistor that stores information in a static random access memory (RAM). In still other applications, cell 100 functions as a micro-electromechanical switch that is adaptable to a variety of applications.

In one preferred embodiment, cell 100 is constructed with at least two membranes. A substantially non-pliable membrane 102 is used as a reference plane for the cell. An electrode, such as a column electrode 104, is printed or otherwise formed on non-pliable membrane. Preferably, electrode 104 comprises a pattern of copper that is printed or otherwise deposited and patterned on non-pliable membrane. Proximate to electrode 104 are a first contact pad 106 and a second contact pad 108 both of which are electrically isolated from electrode 104 and each other. Contact pad 106 is coupled to a power source for powering the display medium. Contact 108, which is closely proximate to but electrically isolated from contact 106, is unpowered but is coupled by a via 112 to display medium 124 and to latch the switch in the ON position. Both contacts 106 and 108 have a coating of chromium 110 applied along the contact's surface to minimize stiction and oxidation of the contact. To prevent electrical shorts, a thin insulator 114 is applied over electrode 104 and portions of the contact 106.

A substantially flexible membrane 118 is maintained in a parallel spaced apart relationship with respect to non-pliable membrane 102 by a spacer layer 1116. Membrane 118 has bridge contact 120 and a second electrode 122 either printed or deposited on membrane 118. Preferably, electrode 122 is a pattern of a metal such as aluminum. It is preferred that the metal have a modulus of elasticity that is similar to the modulus of elasticity of the flexible membrane. Bridge contact 120 is proximate to electrode 122 and is patterned on membrane 118 but electrically separate from electrode 122. Bridge contact 120 is positioned closely proximate to the center of cell 100 and in alignment with contacts 106 and 108 such that it bridges contacts 106 and 108 to form a circuit when the flexible membrane is mechanically switched, or brought into proximity with the non-pliable membrane. Bridge contact 120 also preferably has a layer of chromium applied to its contact surface.

Spacer layer 116 is essentially a frame that extends around cell 100 to support flexible membrane 118 in a spaced apart relationship with respect to non-pliable membrane 102. Conceptually, spacer layer 116 forms a perimeter and defines the boundary of cell 100. Spacer layer 116 creates a region in the interior region of cell 100 into which flexible membrane will intrude when the proper electrical controls are applied to electrodes 104 and 122.

Spacer layer 116 may be a patterned plastic foil that is ultrasonically or chemically bonded or heat welded to membranes 102 and 118. However, it is preferred that spacer layer 116 be defined by a printing process that accurately places ink to define the perimeter of cell 100. Alternatively, spacer layer 116 can be defined by coating non-pliable membrane (or flexible membrane) with a photoresist material that is coated on or applied to the membrane, dried or cured and patterned using well-known photolithography techniques. The thickness of spacer layer 116 is preferably in the range of 0.5 μm to about 50 μm, but can be usefully implemented outside this range as the display size and resolution mandates. It is desirable that spacer layer 116 be as high or tall as possible to compensate for surface variations in the membranes. In most applications, spacer layer will range from about 4 μm to about 25 μm. In general, any suitable fabrication techniques can be employed to create the structures described herein.

Spacer layer 116 is sufficiently elastic to allow some torquing but is sufficiently stiff to support membrane 118. It is to be noted that as used herein, the terms “non-pliable” and “flexible” are used to denote a degree of either rigidity or flexibility so long as the membranes are rigid enough to give the cell the necessary structural integrity and operation.

Typically, selecting a slightly thicker membrane for membrane 102 or a higher elastic modulus than the elastic modulus for membrane 118 achieves sufficient structural stiffness. However, membrane 102 and spacer layer 116, in one embodiment, be sufficiently thin and flexible such that the switch matrix could be twisted, bent or wrapped around an object such as a tree or a pole. It should be apparent that different materials and material properties (dimensions, elastic modulus, etc.) may be used and still achieve the desired functionality.

Membranes 102 and 118 are both preferably selected from material that is both flexible and has a long flexural lifetime. Preferred materials that can meet these requirements include polymers and more specifically, polyimides, polyethylene terephthalate (PET), polyethylene naphthalate (PEN) and many other polymer alloys or elastic material. Although, in one embodiment, non-pliable membrane is substantially rigid, it will be appreciated that absolute rigidity is not necessary to a successful implementation. Thus, non-pliable membrane may be glass or ceramic if high rigidity is desired and weight or cost is not a concern or membrane 102 may be a relatively thick (non-flexible) membrane of the preferred material if weight and costs are to be minimized for the specific application. Depending on the type of material selected for membrane 102 and membrane 118, the flexibility will be inversely proportional to the thickness of the membrane. Thus, the thickness of non-pliable membrane will be determined by the pliability requirement of a particular application, the type of material selected for the membrane and the electrostatic sensitivity of the electrophoretic material, with less sensitive materials demanding a thinner membrane. Useful range of thickness of non-pliable membrane extends from about 10 μm to about 100 μm; however, thicknesses outside this range are contemplated. Flexible membrane may be selected from the same preferred material as non-pliable membrane or may be of a different material. However, flexible membrane will normally be thinner than non-pliable membrane as it is intended to extend from an initial spaced-apart position disposed parallel to the non-pliable membrane to a position where the two membranes are in mechanical contact with each other. Thus, it will be further appreciated that the selected thickness and pliability of membranes 102 and 118 will vary as a function of the material selected and the application.

Because each membrane carries opposing contacts coupled to drive electronics, a circuit is completed whenever flexible membrane 118 is moved sufficiently close to non-pliable membrane 104. When membrane 118 deflects toward membrane 102, bridge contact 120 electrically couples contact 106 to contact 108 and forms a circuit to provide power to the display medium. In one preferred embodiment, display medium 124 is an electrophoretic material that emits light when biased with an appropriate voltage. When the flexible membrane is allowed to return to its spaced apart relationship with respect to membrane 102, the circuit is broken and electrophoretic material no longer reflects light. More specifically, without the attractive electrostatic force between the electrodes, the mechanical force caused by the deflection of flexible membrane causes it to spring away and physically separate from the non-pliable membrane. The physical separation interrupts the flow of power to electrophoretic material 124 causing it to go dark. Thus, cell 100 functions in a substantially identical manner to that of the silicon thin film transistors (TFT) active matrix backplane except that it relies on mechanical forces rather than on the physics of a semiconductor device. The power available to select the switch cell is independent of the power that drives electrophoretic material 124, which provides advantages that the optical display designer does not have if a typical semiconductor backplane is used.

The mechanism for switching cell 100 comes about by creating an electrostatic force to attract flexible membrane 118 to non-pliable membrane 102. With electrostatic forces present, that is, when electrodes 104 and 122 are biased with a voltage differential that is sufficient to create the electrostatic force, flexible membrane will be deflected or pulled toward the non-pliable membrane until the two membranes are in a mechanically engaged relationship. FIG. 2 schematically illustrates the deflection of flexible membrane 118 that occurs when the proper voltages are applied to electrodes 104 and 122. As illustrated, flexible membrane is mechanically deflected until bridge contact 120 engages contact pads 106 and 108. Bridge contact functions to jumper power from contact 106 to display medium 124 through contact 108 and via 112. When the electrode voltage is removed, the mechanical energy stored in flexible membrane 118 causes the electrodes to separate when contact 114 breaks contact with contact pad 106.

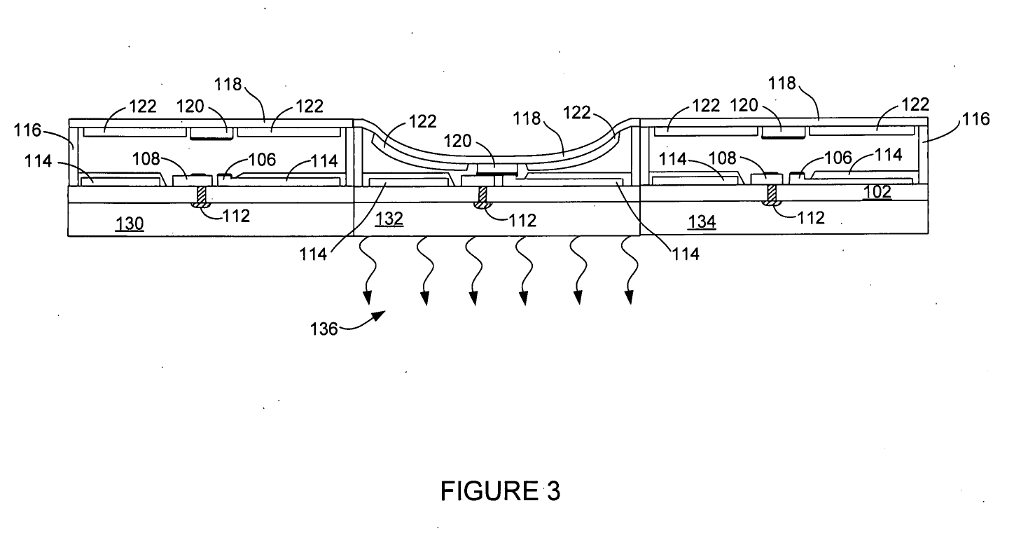

Referring now to FIG. 3, a sectional side view of a portion of a matrix of cells 100 is illustrated. Although only one partial row of cells 130, 132 and 134 is illustrated, it will be understood that many such rows may be provided and that each row may include any number of such cells. Further, column electrodes 122 are only partially shown in each cell although each electrode may extend through many such cells. Alternatively, the column electrodes may be segmented so that a plurality of cells along a common column will be independently selectable. Cell 130, 132 and 134 also include row electrode 104.

When a voltage is applied to column electrode 104, the column is selected and all cells in the column will have a common applied voltage potential. Alternatively, column electrode 104 may be segmented into two or more independently addressable electrodes so that selected portions of a column may be selected. With the column selected, a voltage may be applied to one of the row electrodes 122. Depending on the voltage applied to electrodes 122, the cells may be energized. In FIG. 3, cells 130 and 134 are not energized and are in the OFF state. Cell 132 is energized and is latched in the ON state. In the energized cell 132, contact 120 electrically engages the contact pads 106 and 108.

The voltages applied to the row and column electrodes create an electrostatic attraction between flexible membrane 118 and membrane 102 that cause flexible membrane to deform or deflect into the space created by spacer layer 116. When the row and column electrodes come into proximity, the conductive contacts 106, 108 and 120 are in mechanical and electrical contact and complete a circuit that powers the optical material aligned with each cell as indicated by the radiation arrows 136. When the flexible membrane is not deflected, there is no mechanical or electrical contact and power is not applied to the display medium 124. Thus, when the row electrode is deselected, flexible membrane 118 will spring apart and the flow of power to the optical cell will be interrupted. Interestingly, the power that was stored in the switch mechanism and the optical cell will keep the cells in the ON state for some short duration of time after the row is deselected. This non-linear response is substantially identical to that of the silicon-based active matrix backplane. Thus, with the proper application of voltages, the MEM switches operates as the backplane of an optical display but a refresh voltage must be continually applied to the electrodes prior to loss of the stored energy in order to prevent the loss of the image.

Advantageously, each MEM switch may also be operated in a latched mode, such that once a pixel state is defined, it will remain in that state until changed without any requirement for periodic refresh. The latching mechanism creates a bi-stable display device that minimizes power requirements by eliminating the continual refresh required in prior art displays.

The “latch mechanism” is an area of conductive material that creates the electrostatic structure for maintaining the switch in the closed or ON state after the removal of power from the column electrode. The latch mechanism is also useful for activating the electrophoretic material, e.g., changing the color state of the material from black to white without placing a load on the column and row electrode power supplies.

To see the pattern of the conductive elements in plan view, reference is made to FIGS. 4, 5, 6 and 7, which are not shown to scale. FIGS. 4 and 5 are plan views of non-pliable membrane 102 and the flexible membrane respectively. FIG. 4 shows a conductive electrode pattern and one representative cell layout for the flexible membrane. Arbitrarily, the cell is defined as a horizontal rectangle, but it should be appreciated that a large number of geometric configurations for the cell are possible. Further, the relative areas of certain of the conductive electrodes will be subject to alteration on the basis of the selection of operating voltages, membrane thickness and type of material selected for material 124. The conductive electrode can be manipulated to best use the area available on the basis of material and cell layout necessity. In addition to the conductive electrodes that control the state of the switch, the cell also includes a latching mechanism that enables the cell to function as a static memory after voltage is removed from the column electrode. When a cell is latched in the ON state, the necessity to continually refresh the row and column electrodes to maintain that state over time is eliminated because the switch position, once set, is maintained by the latching mechanism.

The basic layout of the cell includes the spacer layer 116 that defines the boundaries of the cell's column electrode 150. Column electrode 150 is either printed or deposited on non-pliable membrane 102 and then spacer layer 116 is subsequently either printed or bonded to the non-pliable membrane. An insulator is applied to the top of the column electrode so that the electrode will never be in electrical contact with the electrode on the other membrane. Column electrode 150 is coupled to column driver electronics by column trace 152, which also further couples the electronics to additional cells in a single column. The column driver electronics provide the various voltage levels necessary to bias the column electrode during operation to create the electrostatic force necessary to attract the flexible membrane 118 and to return the membrane to the non-deflected position.

Column electrode 150 defines a metal structure that may substantially cover the interior area of the cell within the boundaries defined by the spacer layer 116. The column electrode and trace can be implemented with a large number of conductive materials, including but not restricted to copper, aluminum, chromium, silver, gold, tin, zinc, low temperature ITO and others with copper or aluminum preferred for most applications where the non-pliable membrane is not likely to be twisted or greatly flexed. As illustrated, column electrode 150 has a generally U-shape appearance although other geometric shapes are possible. The column electrode provides the metal area necessary to generate, in conjunction with the row electrode, the electrostatic attraction that will initially pull the flexible membrane into contact with the non-pliable membrane. Depending upon the column driver voltage, the area will be larger or smaller in order to accomplish this task with a larger area requiring a lower voltage.

Each cell further includes a relatively narrow width latch trace 156 and latch trace extension 158 that can both be implemented with the same type of conductive material as described above, and specifically, including but not restricted to copper, aluminum, chromium, silver, gold, tin, zinc, low temperature ITO and others. Within the cell, latch trace extension 158 branches off from the main trace and terminates at a latch contact 160. Latch trace extension 158 is substantially surrounded by a latch pad 162 that includes a contact 164. It is not required in the most basic implementation of the cell to include latch pad 162 and contact 164. Indeed, it is perfectly possible to make the necessary electrical contact between membranes without this separate pad 162 and contact 164.

Contacts 160 and 164 are typically raised, relative to the latch trace extension 158 and latch pad 162, by about 1 μm to 5 μm although the raised aspect is not necessarily required. The contact pad areas are also capable of using a wide variety of conductive materials and standard practice in the switch design field suggests that silver, gold, and other noble and refractory metals would be optimal, with a thin film of chrome or chromium nitride, which acts as an arc suppression/anti-stick coating.

FIG. 5 illustrates the row electrode 170 which is printed or deposited on a very thin polymer material flexible membrane 118. Because of the flexure of flexible membrane, it is important for the elastic modulus of the electrode metal to as closely as possible match the elastic modulus of the polymer. It is also important that row electrode 170 be either printed or a ‘cold’ deposition to avoid melting the flexible membrane during the deposition process. Accordingly, it is preferred that row electrode 170 is an aluminum structure that substantially covers the entire area of the cell within the boundary defined by spacer layer 116. The aluminum has relatively low stiffness so it is able to flex as flexible membrane deflects toward the non-pliable membrane 102.

In the middle of the cell, a small cut-out or opening 172 in the aluminum structure of electrode 170 provides an area for placing a bridge contact 174 that may be aluminum or, preferably, a sandwich of metal comprising an aluminum based and a membrane of another metal or conductor type such as chromium or chromium nitride. Bridge contact 174 is positioned so that it is aligned with contact 164 and latch contact 160. When a cell is selected to be in the ON state, a voltage is applied to the row and column electrodes to generate the attractive force necessary to move the flexible membrane of the cell into mechanical and electrical contact. In the ON state, contacts 160 and 164 are bridged by bridge contact 174 to form a mechanical and electrical connection that energizes the electrophoretic material in the cell. After a stable mechanical state is achieved, power is applied to latch contact 160 by latch electronics along latch trace 156 to maintain the electrophoretic material in an energized state. The voltage on column trace 152 may then be removed because the flexible membrane is held in electrical and mechanical contact by the electrostatic forces generated between the voltages applied across contact 174 and latch contact 160. With the electrical circuit maintained, the electrophoretic material remains energized until the latch voltage is also removed.

Importantly, the latch power does not need to be in applied to latch pad 160 until after mechanical contact is stable. Further, the risk of arching or “hot switching” is avoided because latch trace 156 is not energized until after the mechanical contact is stable and a low resistance connection established. Obviously, for grey scale applications or color displays, it may be unavoidable for hot state changes to occur. However, by synchronizing the application of power only after the mechanical connection is stable, the risk of arcing that would be expected under normal operating circumstance is greatly reduced and virtually eliminated. It will be appreciated that arching is a fundamental limitation of the useful lifetime of this active matrix backplane, so by eliminating the risk of arching, an enormous improvement in lifetime and reliability is achieved.

As a further enhancement to minimize the risk of arching, sulfur hexafluoride gas may be introduced into the sealed cell in the event that there may be some current flowing through the contacts during the time that the power on the latch pad is removed. The combination of applying power after mechanical contact is established and stable and removing power before the mechanical connection is broken together with the introduction of the gas, contact life will be improved and the likelihood of arcing at any time during the switch cycle eliminated.

As will be appreciated, the electrostatic field generated by the energizing latch trace 156 maintains the electrostatic field needed to energize the state of the electrophoretic material provided the thickness of non-pliable membrane is sufficiently thin. In alternative embodiments, an electrode may be formed in physical contact with electrophoretic material 124 to directly energize the material. Physical contact with the material is achieved by forming a via through non-pliable membrane and either printing or depositing an electrode on the side of non-pliable membrane facing away from flexible membrane. It is important to remember that in this implementation, the electrophoretic material is on the side of membrane 102 that is opposite that of the conductive elements 150 and 156. It is also important to note that there is no electrical connection between the column electrode 150 and latch trace 156 in this implementation. While this is not completely obligatory, for this particular implementation, the lack of connection works best because the column electrode driver is not used to bias electrophoretic material 124. Note further that thin dielectric coatings that reduce the leakage of the electrical charge from the latch trace to the surrounding conductive paths is a useful improvement in this invention, and such coating are well known in the electrical engineering industry.

As illustrated in FIGS. 4 and 5, spacer layer 116 need not form a contiguous perimeter around the cell. Rather, it is desirable that a plurality of gaps 176 be provided to enable the passage of air present in the gap between membranes 102 and 118. Thus, whenever flexible membrane moves toward non-pliable membrane as a cell is switched from an OFF state to an ON state, the air present in the gap can move to other nearby cells. In this manner, the electrostatic forces will not have to overcome the increase in pressure caused by compressing the air, which would occur if the cell were hermetically sealed. In the preferred embodiment, as the flexible membrane 118 is moved toward non-pliable membrane 102, air is forced out of the cell and into surrounding cells through the gaps 176. When the flexible membrane 118 is released and is moving to an OFF state position, air can rush back into the cell to assist flexible membrane 118 in overcoming stiction or vacuum suction created by a sudden increase in cell volume.

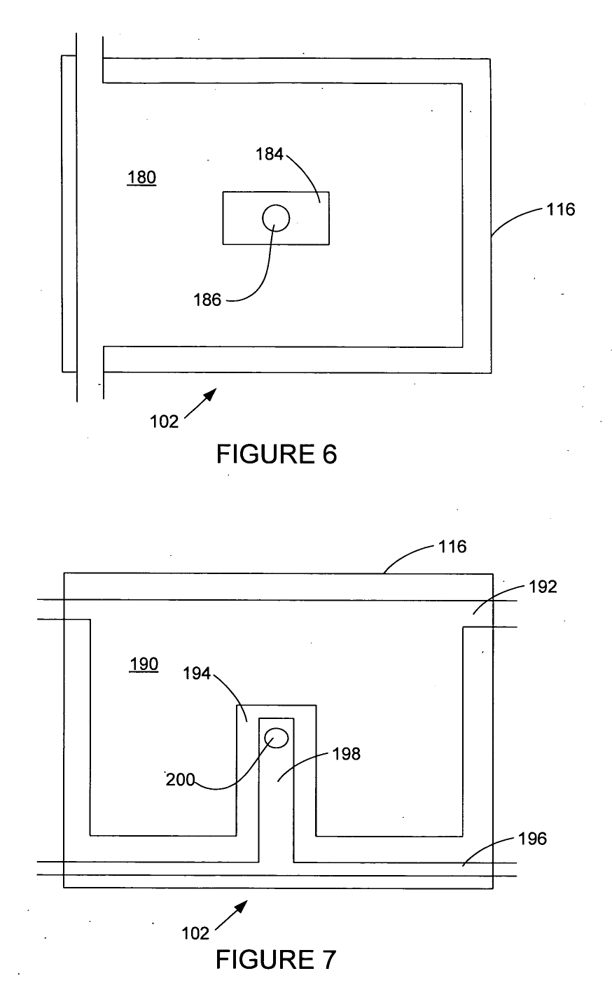

FIG. 6 is a plan view of another embodiment of cell 100 illustrating an embodiment that does not have a separate latching mechanism and which is suited for optical displays having bi-stable optical media where once set, the optical media will remain in that state until changed to another state. In this embodiment, column electrode 180 comprises a structure of metal or other conductive material that substantially fills the area of the cell defined by spacer layer 116 on non-pliable membrane. Copper is the preferred conductor for electrode 180 although other conductors may be used such as, by way of example, aluminum, chromium, silver, gold, tin, zinc, low temperature ITO and others. Again, an insulator is applied to the top of the electrode so that the electrode on one membrane will never be in electrical contact with the electrode on the other membrane. Column electrode 180 is coupled to column driver electronics by column trace 182. In the middle of the cell, a small cut-out or opening 184 in the metal structure of electrode 180 provides an area for placing a contact pad 186. Contact pad 186 is raised by about, relative to the column electrode 180 by about 1 μm to 5 μm. Contact pad 186 may be copper, aluminum, a sandwich of metal comprising an aluminum base and another metal such as chromium or chromium nitride, silver, gold or other noble or refractory metals. Contact pad 186 may further include a thin film of chromium nitride to act as an anti-stick and arc suppression coating.

FIG. 7 illustrates the row electrode 190 that is printed or deposited within the cell, as defined by spacer layer 116, on the flexible membrane 118. Row electrode 190 is coupled to a row driver electronics that sets the appropriate voltage potential on electrode 190 by row trace 192. As is well understood, the column and row traces 182 and 192, respectively, comprise a matrix where all cells in a display device may be sequentially scanned and selectively set to either the ON or OFF state depending on the displayed data. This is accomplished by selecting one of the column electrodes in the matrix and then sequentially biasing the row electrodes to either set each cell as the juncture of the row and column electrode to the ON or OFF state. The next column electrode in the matrix is then selected and the row biasing process is repeated. This process continues until all columns have been selected before beginning again with the first column.

Because row electrode 190 and row trace 192 are printed or deposited on the flexible membrane, aluminum is the preferred metal for defining both. Row electrode 190 fills most of the area within the cell and has a U-shape that defines a region 194. This region 194 encompasses the central portion of the cell, extends along one edge of the cell, and is not covered by row electrode 92. A display trace 196 is printed or deposited in the portion of the region 194 along the edge of the cell and in parallel with the row electrode 190 is used to power the display media once a switch has established a connection with the flexible layer 118. A branch or stub 198 branches off of the display trace 196 and extends from the edge of the cell into region 194 and more specifically into the center of the cell. Within region 194, a display power contact 200 is printed or deposited on top of stub 198 such that display power contact 200 is in the approximate middle of the cell and in alignment with contact pad 186 (FIG. 6). Power contact 200 may be aluminum, silver, gold, and other noble and refractory metals,

When the column electrode 180 is selected and the row electrode 190 is biased to switch the cell at the intersection of the row and column electrodes in the matrix to the ON state, the display power trace will provide direct power to the display media. Because the display power trace is always biased with the proper voltage to energize the pixel, it functions to set each cell in the ON state. Because of the limited function of the display power trace, it does not require the large surface area of the electrodes and the voltage on the trace is set to a level that is sufficient to set the display state of the display media. Again to minimize arcs, power need not be applied until after the mechanical connection between the flexible and non-pliable membranes is established.

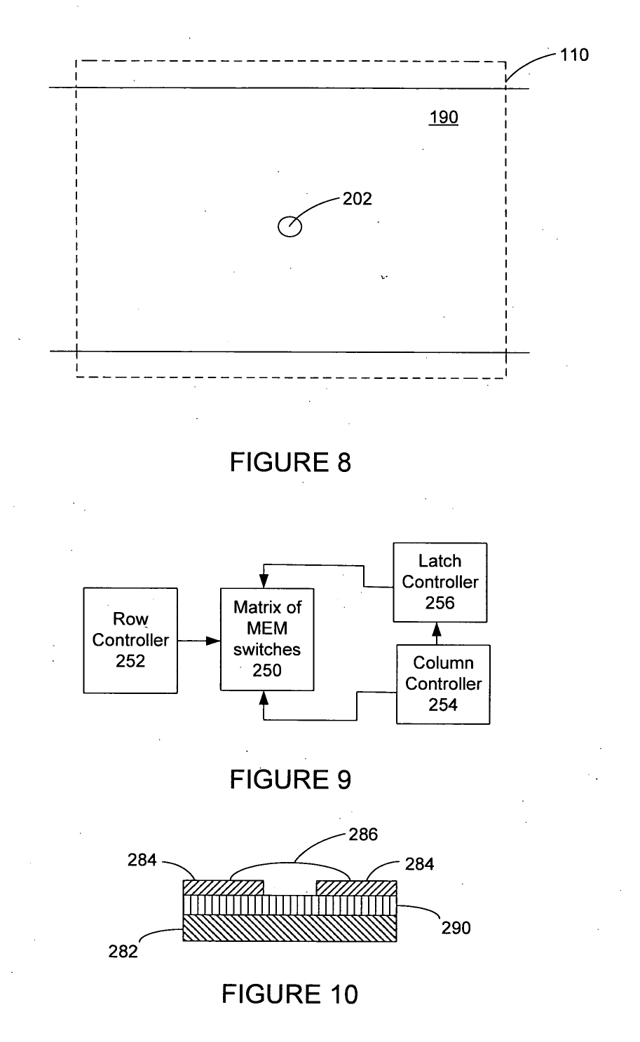

In an alternative embodiment where the display material does not place a significant load on the row and column driver electronics, it is possible to implement the row electrode as illustrated in FIG. 8. Here, row electrode 190 includes a contact 202 positioned in the approximate geometric middle of the cell in alignment with contact pad 186. In this embodiment, power is ‘vampired’ from the row driver to also bias electrophoretic material 124 when the cell is in the ON state. This embodiment is well suited if the electrophoretic material 124 or other display material has a relatively high impedance.

For other displays that require a high current to drive the display, has a relatively low impedance or that are otherwise incompatible with the power requirements of the row and column drivers, the display power trace can be used to separate the function of controlling the switch from the function of energizing the pixel. To illustrate, in an OLED flat panel display, the backplane must provide a high current whenever a pixel is switched to the ON state. With a large number of pixels in the ON state, the current load could reduce the voltage on the column and row drivers thereby slowing down the switching rate of the switches. By separating the power source that drives the pixels from the power source that controls the switch, the voltage that generates the electrostatic force is not affected even if a large number of pixels are in the ON state simultaneously.

FIG. 9 illustrates one embodiment for controlling the matrix of MEM switches to generate a displayed image. A matrix of MEM switches 250 is coupled to a row driver 252 that controls the application of voltage to each of the row electrodes in the matrix 250. Matrix 250 is also coupled to a column driver 254 that controls the selection of column voltage to each of the columns in matrix 250. As will be apparent to one of skill in the art, it is possible to set up a row voltage on each row of matrix 250 and then sequentially select each of the columns in the matrix. Critical to the long life operation of the matrix, latch driver 254 is coupled to column driver 252 so that when a column is selected the latch voltage in that row is switched off until after the mechanical settling time has elapsed after which, the latch voltage may be applied to that column. One skilled in the art will further appreciate that each driver may be associated with a discrete power supply capable of supplying the voltage and current required for driving its respective portion of matrix 250. Alternatively, each driver may include an integral power supply. In alternative embodiments, latch control can come directly from either the column controller or the row controller or from an external signal that coordinates all controller functions.

Refer now to FIG. 10 where the operation of a switch is described for a monochrome display (or a display that generates only primary colors and/or a memory device). More specifically, FIG. 10 shows the voltage-timing diagram for controlling the operation of the cell illustrated in FIGS. 4 and 5. Control requires three voltages: a column voltage 220, a row voltage 222 and a latch voltage 224. In typical operation, the column voltage will be about zero volts when the respective column of the matrix is not selected. This state is illustrated at time prior to t₁. When the column is selected, the voltage will change from zero volts to about 10 volts. Similarly, the row voltage will be zero volts when it is selected to about 5 volts when it is not selected. The latch voltage will be zero volts and will switch to a higher voltage when the switch is to be latched. Typically, the latch voltage will be a function of the display media and the cell geometry and may be in the range of between 3 volts to 50 volts with 40 volts being illustrated in FIG. 10 as a representative typical voltage.

During operation, all of the rows of the matrix are initially set to either zero volts (if the switch is to be in the ON state) or to 5 volts (if the switch is to be in the OFF state which is indicated by the dashed line 226) as indicated at t₁. Then a column in the matrix is selected, as indicated at time t₂, when the column voltage 220 switches from zero volts to 10 volts. At this point, cells having a differential of about 10 volts between the row and column voltages will be in the ON state because of the electrostatic forces generated by the voltage potential across the row and column electrodes. Similarly, all cells in the selected column having a row voltage 222 of 5 volts will be in the OFF state because the voltage potential across the row and column electrodes will be insufficient to deflect membrane 118.

After the column voltage 220 has switched to the high voltage, the latch trace voltage 224 is then switched from zero volts to the 40 volt level at time t₃. It is important to realize that the time delta between time t₂ and t₃ must be sufficient to allow a stable mechanical connection to be established between the membranes 102 and 118. If the cell is in the OFF state, a latch pad voltage 228 will remain at zero volts as indicated by the dashed line 230. However, if the row voltage is at zero volts, the latch pad voltage will complete the circuit with contact pad 174 (see FIG. 5) and hold the switch in the ON state. Latch voltage may be maintained at the latch pad until the column is next selected. At this point, the latch voltage connection is maintaining the cell in a stable and latched condition, the column driver power can be removed, and the row driver power is “don't care.” A sufficiently high voltage differential will be established between the latch pad area and the row driver area, that regardless of the row voltage, the cell will remain latched. The cell will remain in an ON state until latch voltage 224 is removed. In this manner, a latched display does not require continual refresh. It is assumed that the latch voltage trace 156 (FIG. 4) will be connected to external circuitry interfacing to the row/column drive circuitry. Latch voltage 224 is not a typical function of current row/column circuitry, and it must be synchronized with the application of the row voltage for each column. Suffice it to say that latch voltage 224 and latch pad voltage 228 are held at a high potential that is perhaps several times the potential of the column voltage for the period where the display image must be sustained. When latched, it does not matter whether the row voltage 222 is at zero volts or 5 volts because the high voltage is sufficient to hold the cell in the ON state.

At some point, it will be desirable to un-latch the cell. In order to do this, such as indicated at t₁ in FIG. 10, the latch voltage 224 is switched from the high latch voltage level to zero volts so that the voltage is removed before the cell can break the mechanical connection. By rapidly removing the latch voltage, there is no current available when the connection is broken. Clearly, it is desirable to minimize the capacitance of the latch trace so that the voltage can be quickly removed in less that about 30 to 100 milliseconds.

Alternatively, the latch voltage can be coordinated with column voltage when the display is to be changed yet still selectively retain the information previously stored. More specifically, by dropping the latch voltage just before the column is next selected (that is about 30 ms before the column is selected), the switch can be “re-latched” before the mechanical break or can be allowed to transition to the OFF state if there the cell need no longer be in the ON state.

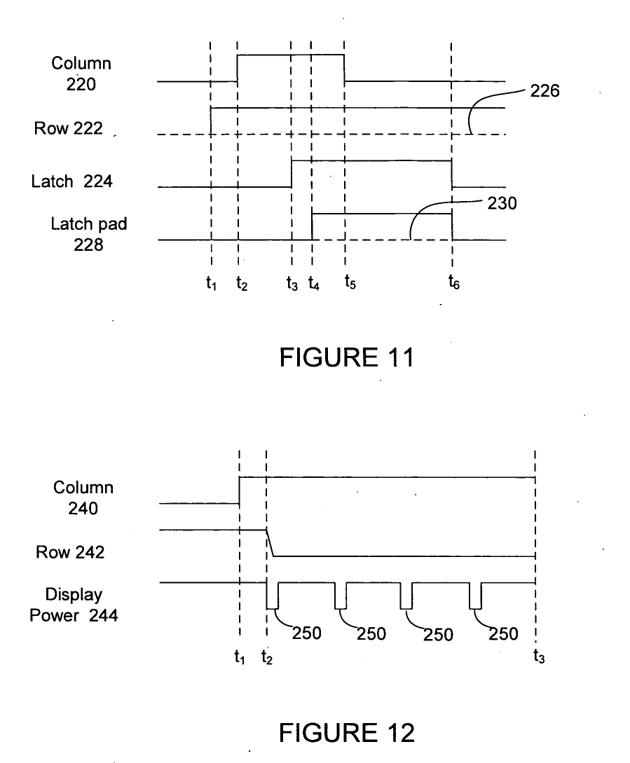

Refer now to FIG. 11 where the voltage-timing diagram for a cell in a backplane that drives a grey scale display is illustrated. More specifically, FIG. 11 shows the voltage-timing diagram for controlling the operation of the cells illustrated in FIGS. 4 and 5 (latch mechanism) and in FIGS. 6 and 7 (no latch mechanism). In this embodiment, if a pixel is unselected for an entire frame (from t₁ to t₃), it will be black (switch is in the OFF state) and if a pixel is selected for the entire duration of the frame, it will be white (switch is in the ON state). Controlling the switch operation of the cell again requires three voltages: a column voltage 240 a row voltage 242 and a display power voltage 244.

During operation, all of the rows of the matrix are initially set to five volts as indicated at time prior to t₁ and the column is not yet selected so column voltage 240 is set to zero. The display power 244 is set to 40 volts although it is to be understood that this voltage level is dependant on the requirements of the display media. Display power 244 is not applied to the pixel until the switch is in the ON state. It should be noted that the applied voltage may be either DC or AC voltage depending on the application.

Then at time t₁, the column is selected for the entire duration of a frame and the column voltage 240 switches from zero volts to 10 volts. Since the row voltage is at five volts, the cell will not switch to the ON state but will remain in the OFF state with a black pixel. The row voltages 242 are held for a length of time sufficient to achieve the desired grey scale and then switched to zero volts as indicated at time t₂. When the row voltage switches to zero volts, the switch will change to the ON state. However, it may be necessary to temporarily switch the display power voltage 244 during the row voltage transition to avoid a “hot switch.” Accordingly, the display power voltage level is also switched to a low state when row voltage is to be switched. Once the mechanical switching process is complete, the display power voltage 244 is again raised to 40 volts, about 30 milliseconds to about 100 milliseconds later (depending on the mechanical response time of the switch) except this time, display power pad is able to complete the electrical circuit and energize the display media.

It is possible to define 4, 8, 16 or more shades of grey scale by defining transition windows during each frame. As illustrated in FIG. 11, there are 4 transitions 250 in a frame 252 and the row voltage is allowed to change from 5 volts to zero volts or from zero volts to 5 volts only at one of transitions 250. At each transition, the display power 244 is quickly dropped for about 30 to 100 milliseconds to allow the switch to stabilize and then it is raised to 40 volts to energize the display media. In this way, it is possible to easily coordinate power switching with mechanical switching to provide grey scale images using the present invention without damaging the contacts by making or breaking a connection under power. If the row voltage does not change, the transition 250 needs to be generated by the display power. Analog switching, in which no voltage drop of the latch trace takes place is allowed, although it is understood that it may impact the display lifetime.

It is well understood in the art that the useful life of a switch that is caused to “make” or “break” under power is finite and perhaps not exceeding a few million cycles. With the present invention, however, power can be removed from the contacts during the transition from OFF to ON. The power is applied only after the switch contacts have settled to turn on the optical cells. In addition, the power can be removed from the cell before the switch is made to break. In this way, the switch contacts are not subject to the arcing at make and break, that is well understood to cause limited lifetime.

In the event that it is necessary to provide grey scale to the display, the cells may be transitioned under power in limited circumstances. In this event, it is desirable that any of the well-known classes of gases, such as, sulfur hexafluoride, that can suppress the arcing of switch contacts be disposed in the cell cavity. Because of the high molecular weight of these types of gases, it is possible to encapsulate the gas in the polymer switch cell assembly with every expectation that the gas will not soon diffuse through the polymer foils. The inclusion of sulfur hexafluoride into the switching cells allows a dramatic increase in the lifetime of the switch contacts under circumstances where it is necessary to make or break a switch contact that is powered.

The present invention provides a matrix of micro electromechanical (MEM) switches manufactured using low cost manufacturing techniques and may be advantageously formed on a variety of plastic or other flexible membranes or foils. The MEM switches can be manufactured in an array that provides sufficient number of switches to drive an optical display device for markedly reduced processing costs. It is herein disclosed that while mechanisms familiar to the semiconductor backplane display industry could be used to manufacture these displays, such non-obvious manufacturing equipment as rotary printing presses or screen printing presses might also be usable for the manufacture. Clearly, the cost reduction is substantial and immediate.

To manufacture the array, a roll of a relatively non-pliable foil of a desired width, such as 24 inches, and a couple of miles in length is secured. The thickness of foil may range from 10 μm to 100 μm. Thicker foils are possible but the thickness must be matched to the intended application. The foil is preferably a polymer, polyimide, PET, PEN or other similar material.

The first process step is laser ablation to create via holes in the foil. The hole structures could be defined by photolithography methods and then etched but would be more labor intensive to complete. When the hole structures are established, the foil is run through a catalytic solution and placed into an electroless plating bath so that both surfaces and the via holes will be coated with metal to a thickness of about 0.5 μm to about 10 μm and preferably with about 2.0 μm to about 3.0 μm so long as the metal is capable of carrying the requisite current to energize the display. For membrane 102, the metal is preferably copper.

A resist pattern is then printed on the copper-foil laminate using roll-to-roll printing equipment. The resist pattern is a lacquer (lacquer being defined as a term of art for an etchant resisting material most likely of simple organic or polymer origin) layer that is allowed to dry and then the laminate is placed into an etchant to remove copper that is not coated by the resist pattern. The pattern resolution may enable the printing of switch cells as small as about 20 μm by 20 μm although larger resolutions are usable for large display applications such as an outdoor sign. Thus, any open or expose copper will be etched by the etchant. The lacquer is a loaded ink that is printed such that it is thicker than the underlying copper with the minimal requirement being that the lacquer be pinhole free and resistant to the copper etchant.

The laminate is then immersed in an organic solvent to remove the lacquer with the solvent being dependent on the type of lacquer and polymer foil used.

A second layer of lacquer is then printed to define the contact area. The contacts are built up using the same electroless plating method because the coating rate is relatively fast and is well suited for roll-to-roll printing applications. It is possible to use vacuum sputter or evaporation to deposit the metal but the need to perform the coating in a rapid manner dictates that the plating method be preferred.

The lacquer layer may be left on the electrodes as insulation. FIG. 13 illustrates a sectional profile of a contact as plated onto the copper layer. Specifically, the copper electrode 280 is shown on one side of membrane 282. A lacquer layer 284 has been patterned to define a hole through the lacquer layer where contact 286 will be plated. With this process, there is some over plating but with the lacquer providing insulation, contact 286 will tend to acquire a dome-like appearance extending out over the lacquer edges. In a preferred embodiment, the contact should extend above the lacquer by about 1.0 μm to about 5.0 μm.

It is important that the lacquer thickness at this step is minimized if it is to be left on as an insulating layer over the copper. Because the lacquer acts as a dielectric layer, it will dissipate the electrostatic charge between the electrodes. To illustrate, air has a dielectric constant of 1.0 and lacquer has a dielectric constant of about 4.0. Thus for every micron of lacquer thickness, it has the same effect as if the electrodes were moved further apart by approximately 4 um. Thus, it is desirable to minimize the lacquer thickness so that it does not have more than a negligible impact on the electrostatic force but thick enough that the electrodes do not arc when they get close together. Fortunately, it is possible to maintain the lacquer thickness to between about 0.5 μm and 3.0 μm although thinner and thicker lacquers may be used in some applications. Other methods for forming the contact and printing an insulating layer of lacquer are possible. For example, screen printing or Gravuer printing techniques may be easily used.

The spacer layer 116 is screen printed on top of membrane 102 rather than using photolithography techniques and comprises a polymer-based (plastic-like) ink. The height of spacer layer 116 is determined by the amount of ink that is applied to the membrane. As noted above, the spacer layer 116 may be perforated so that air can readily move in and out of the cell as the membrane displaces the air. In other embodiments, the spacer layer 116 is preferably contiguous so that air is not pumped into cells. The perimeter may be fairly wide so that it better can resist lateral stresses as the flexible membrane deflects and then returns to the OFF state. There is no requirement that spacer layer 116 be rigid. Indeed, it is acceptable that the layer be allowed to move laterally or to bend slightly relative to an axis perpendicular to the membranes.

The critical component in manufacturing a cell array is in careful selection of the flexible membrane material, its physical properties and the elastic modulus. Of these properties, the elastic modulus is the most critical. The elastic modulus must be as low as possible consistent with proper functioning and manufacturability. To illustrate, consider that copper has an elastic modulus on the order of 130×10⁹ Pascals (130 GPascals) while polymer materials such as PET have an elastic modulus on the order of 1 GPascal to about 5 GPascal. Clearly, there would be significant incompatibility if copper of significant thickness were used on the flexible membrane. Indeed, the elastic modulus of the flexible membrane may usefully range from about 1 MPascal to about 1 Gpascal. Accordingly, aluminum is the preferred metal for the row electrode because the elastic modulus of aluminum is about 70 GPascals. With a very thin aluminum layer its mechanical properties do not dominate. The flexible membrane is attached to the spacer layer by ultrasonic welding, adhesive bonding or similar known technique.

Due the thin foil-like nature of the flexible membrane, it is difficult to deposit metal and pattern the metal using photoresist without potentially melting the membrane. No claim is made that this process is impossible, but only that greater engineering of the process is required for success using conventional photoresist processes. Accordingly, one preferred method for depositing the aluminum is to pattern the membrane with a layer of oil to define the area of the membrane where metal is not desired. The membrane is then placed in a vacuum and the aluminum is sputtered onto the membrane. As the aluminum hits the oil, the oil is vaporized and creates a cloud through which prevents the metal from being deposited. The areas of the membrane without the oil will receive a thin coating of aluminum.

Other important characteristics in designing a cell are the spacing between membranes, the elastic modulus, and the size of the cell and the electrical properties of the display media. For example, in one embodiment, the thickness of the flexible membrane will range from about 2 μm to about 25 μm while the aluminum will be about 300 Angstroms to about 1,000 Angstroms thick with 400 to 500 Angstroms being a typical thickness. In another embodiment, the flexible membrane is a 6 μm thick PET foil that is spaced above the other membrane at a height of about 4 μm (that is the gap between the flexible foil and the non-pliable foil is 4 μm). The aluminum electrode has a thickness of 500 Angstroms and the cell size is a 1 mm by 1 mm rectangle.

With the present invention, it will be appreciated that it is possible to replace the silicon-on-glass thin film transistors (TFT) based backplanes with a matrix of MEM switches that are readily manufactured using inexpensive manufacturing equipment and printing process techniques. Further, it will be appreciated that the present invention enables the manufacture of scalable large optical displays on rigid or flexible plastic membranes at low cost that have an adequate and useful lifetime. Further still, the present invention enables the manufacture of optical displays that may be flexed or twisted into novel shapes while still maintaining the display properties.

There are many existing products, and potentially a large number of new products, that will benefit from an array of switches laid out in matrix pattern (sometimes uniform, sometimes not, depending on the application). With the present invention, it is possible to use the opened (or closed) switch to activate a variety of devices so needing such a switch.

With embodiments of the present invention, the array switches may include one or more of the following attributes: (a) may be physically scaled depending on the application, (b) may switch either AC and DC voltages, (c) may switch either high or low voltage, (d) may switch high or low current, and (e) may be either a momentary or latched switch. The most common need for such an array today is for flat panel displays to replace the expensive backplane based on silicon transistors layered onto glass substrates.

It will further be appreciated that one or more of the elements depicted in the drawings/figures can also be implemented in a more separated or integrated manner, or even removed or rendered as inoperable in certain cases, as is useful in accordance with a particular application.

Although the invention has been described with respect to specific embodiments thereof, these embodiments are merely illustrative, and not restrictive of the invention. For example, although the invention has been discussed primarily with respect to a two-dimensional array, many other configurations or arrangements are possible. In other embodiments it may be desirable to use other than row/column driver addressing; such as where a concentric circular arrangement is used, a random arrangement, etc. A configuration can be multi-dimensional, as where two or more cells are stacked vertically so that a pixel can be defined by multiple (e.g., red, green and blue) independent display elements. Naturally, in such a stacked configuration the cells on top should be transmissive to light emitted or reflected by underlying cells.

Although the invention has been discussed with respect to a display system, other applications are possible. For example, the array of cells can be applied with electrostatic fields by laser, electron beam or other particle or energy beam, pressure, etc., similar to technologies used in imaging systems (e.g., copiers, charge coupled devices, dosimeter, etc.) or other systems. In such an application, the driver circuitry can be replaced with sensing circuitry to detect whether a cell is in an open or closed position. Thus, a sensing array can be achieved. Embodiments may include various display architectures, biometric sensors, pressure sensors, temperature sensors, light sensors, chemical sensors, X-ray and other electromagnetic sensors, amplifiers, gate arrays, other logic circuits, printers and memory circuits.

Functionality similar to that discussed herein may be obtained with different configurations and arrangements, sizes or combinations of components. Use of the term microelectromechanical (MEM) is not intended to limit the invention. Embodiments may use components of larger or smaller size than those described herein. In other designs, components may be omitted or added. For example, additional contact pads on either the non-pliable or flexible membranes can be added. A different contact arrangement may also allow for only two contact surfaces rather than the three described herein. In other embodiments, both membranes may be made flexible. Other variations are possible.

Other types of force than electrostatic may be used to bring membranes into proximity. For example, electromagnetic, applied pressure (e.g., atmospheric or gaseous, liquid, solid), gravitational or inertial, or other forces can be used. Rather than use a force to bring two membranes into proximity, another embodiment can have an un-energized state of membranes in proximity (i.e., a closed switch state) and can use a force to cause the membranes to be brought out of proximity (i.e., an open switch state). For example, an electrostatic force can be used to cause the membranes to repel each other and break a contact connection.

Any signal arrows in the drawings/Figures should be considered only as exemplary, and not limiting, unless otherwise specifically noted. Furthermore, the term “or” as used herein is generally intended to mean “and/or” unless otherwise indicated. Combinations of components or steps will also be considered as being noted, where terminology is foreseen as rendering the ability to separate or combine is unclear.

As used in the description herein and throughout the claims that follow, “a,” “an,” and “the” includes plural references unless the context clearly dictates otherwise. Also, as used in the description herein and throughout the claims that follow, the meaning of “in” includes “in” and “on” unless the context clearly dictates otherwise.

The foregoing description of illustrated embodiments of the present invention, including what is described in the Abstract, is not intended to be exhaustive or to limit the invention to the precise forms disclosed herein. While specific embodiments of, and examples for, the invention are described herein for illustrative purposes only, various equivalent modifications are possible within the spirit and scope of the present invention, as those skilled in the relevant art will recognize and appreciate. As indicated, these modifications may be made to the present invention in light of the foregoing description of illustrated embodiments of the present invention and are to be included within the spirit and scope of the present invention.

Thus, while the present invention has been described herein with reference to particular embodiments thereof, a latitude of modification, various changes and substitutions are intended in the foregoing disclosures, and it will be appreciated that in some instances some features of embodiments of the invention will be employed without a corresponding use of other features without departing from the scope and spirit of the invention as set forth. Therefore, many modifications may be made to adapt a particular situation or material to the essential scope and spirit of the present invention. It is intended that the invention not be limited to the particular terms used in following claims and/or to the particular embodiment disclosed as the best mode contemplated for carrying out this invention, but that the invention will include any and all embodiments and equivalents falling within the scope of the appended claims.

1. A display system comprising:
a first membrane and second membrane maintained in a spaced apart relationship by a intermediate layer, said intermediate layer defining a plurality of cells configured as a matrix;
within each cell, a column electrode printed on one side of said first membrane and a row electrode printed on an opposing side of said second membrane such than when a bias exists, said first membrane is deflected toward said second membrane;
a pair of contacts one of which is patterned on said first membrane in proximity to said column electrode and the other of which is patterned on said second membrane in proximity to said row electrode, said pair of contacts completing an electrical circuit when said first membrane is deflected toward said second layer; and
a display media that is biased to an ON state when said pair of contacts complete said electrical circuit.

2. The display system of claim 1 further comprising a latching mechanism.

3. The display system of claim 2 wherein said latching mechanism comprises:
an electrical latch contact patterned on said first membrane in proximity with said contact patterned on said first membrane; and
means for connecting said latch contact to a power source, said power source independent from the power source that biases the row and column electrodes.

4. The display system of claim 2 wherein said latching mechanism further comprises means for maintaining said first membrane in close proximity to said second membrane after said bias is removed.

5. The display system of claim 2 wherein said latching mechanism further comprises means for energizing said display media after said bias is removed.

6. The display system of claim 1 wherein said first and second membrane are maintained about 4 μm apart until a bias exists between said row and column electrode.

7. The display system of claim 6 wherein said intermediate layer has a height of about 4 μm.

8. The display system of claim 1 wherein said intermediate layer comprises a perforated perimeter that defines the boundary of a cell.

9. The display system of claim 8 wherein said perforations permit the passage of air to adjacent cells when said first membrane is deflected toward said second membrane.

10. The display system of claim 8 wherein said first and second membranes are fixedly attached to said intermediate layer.

11. The display system of claim 8 wherein said first and second membranes are ultrasonically welded to said intermediate layer.

12. The display system of claim 1 wherein said intermediate layer forms a substantially contiguous layer that defines the boundary of each cell.

13. The display system of claim 1 wherein said display media comprises an electrophoretic material that changes from one state to another state in the presence of an electric field induced by the bias applied across said row and column electrode.

14. The display system of claim 1 further comprising a via in said first membrane, said via coupling a bias potential form said electrical connection to said display material through a direct contact.

15. The display system of claim 14 wherein said display material is an organic light emitting diode (OLED) that emits light when subject to a bias, said bias provided to said display material through said via.

16. The display system of claim 1 wherein said second membrane is a flexible foil having a thickness of about 6 μm and said electrode comprises a thin layer of aluminum.

17. The display system of claim 16 wherein said first membrane is selected from the group of polymers, polyimides, poly(ethylene terephthalate) (PET) or PEN

18. The display system of claim 16 wherein said electrode comprises a layer of aluminum having a thickness of between about 300 Angstroms to about 500 Angstroms.

19. The display system of claim 16 wherein said electrode comprises a layer of aluminum having a thickness of between about 200 Angstroms to about 1000 Angstroms.

20. The display system of claim 19 wherein said contact on said second membrane comprises a layer of aluminum having a thickness of at least 200 Angstroms.

21. The display system of claim 16 wherein said contact further comprises a surface coating of chromium.

22. The display system of claim 16 wherein said contact further comprises a surface coating of chromium nitride.

23. The display system of claim 1 wherein said bias comprises a voltage differential of about ten volts.

24. The display system of claim 23 wherein said latch power source comprises a voltage of between three volts and about 50 volts.

25. The display system of claim 23 wherein said latch power source comprises a voltage of about 40 volts.

26. In a display system comprising:
a matrix of micro electromechanical switches controlled by biasing a pair of opposing electrodes to selectively switch said switches from an OFF state to an ON state or from an ON state to an OFF state;
a display media that is biased to an ON state when said switch is switched to an ON state; and
means for minimizing arcing when said switches in said matrix of switches change from an OFF state to an ON state or from an ON state to an OFF state.

27. The display system of claim 26 further comprising means for selectively latching said switches such that said switches are set to a state by a first bias voltage and then held in said state after said first bias voltage is removed by a second bias voltage.

28. The display system of claim 26 wherein said minimizing means comprises the coordinated application of said second bias during the transition from an OFF state to an ON state and applying said second bias after said switch has established a stable connection.

29. The display system of claim 26 wherein said display medium is an electrophoretic material or other display medium such as OLED or liquid crystal.

30. The display system of claim 26 wherein said display medium is an organic light emitting material.

31. The display system of claim 30 further comprising means for transferring said second bias voltage directly to said display material.

32. An arrangement of micro electromechanical (MEM) switches comprising:
a first membrane on which is printed a column electrode;
a spacer layer for defining a plurality of cells with each cell comprising a MEM switch;
a second membrane maintained in a substantially parallel, spaced apart relationship with respect to said first membrane by said spacer layer; said second membrane having a row electrode printed on at least one side of said membrane;
means for deflecting said second membrane to make mechanical contact with said first membrane in at least one selected cell;
electrical components, printed on opposing sides of said membranes to form an electrical circuit when said first and second membranes are in mechanical contact; and
means for energizing a display medium.

33. The matrix of MEM switches of claim 32 wherein each of said cells controls the display state of a pixel.

34. The matrix of MEM switches of claim 32 wherein said spacer comprises a perforated layer that allows air to exit a cell when said membrane is deflected toward the other membrane.

35. The matrix of MEM switches of claim 32 wherein said switches are manufactured using printing techniques.

36. The matrix of MEM switches of claim 32 further comprising means for selectively latching said switches.
